(19) United States
(12) Patent Application Publication
(10) Pub. No.: US 2024/0395979 A1
(43) Pub. Date: Nov. 28, 2024

(54) RADIATION-EMITTING SEMICONDUCTOR COMPONENT, AND METHOD FOR PRODUCING A RADIATION-EMITTING SEMICONDUCTOR COMPONENT

(71) Applicant: ams-OSRAM International GmbH, Regensburg (DE)

(72) Inventors: Christopher Wiesmann, Barbing (DE); Heribert Wankerl, Laberweinting (DE); Laura Kreiner, Regensburg (DE); Rainer Butendeich, Sinzing (DE); Sandra Sobczyk, Regensburg (DE)

(21) Appl. No.: 18/690,938

(22) PCT Filed: Aug. 11, 2022
(86) PCT No.: PCT/EP2022/072588

§ 371 Date: Mar. 11, 2024

(30) Foreign Application Priority Data
Sep. 15, 2021 (DE) 10 2021 123 818.8

(51) Int. Cl. H01L 33/50; H01L 33/22; H01L 33/58; H01L 33/60

(52) U.S. Cl. CPC H01L 33/50; H01L 33/22; H01L 33/58; H01L 33/60; H01L 2933/0041; H01L 2933/0091

(57) ABSTRACT

In an embodiment a radiation-emitting semiconductor component includes a radiation-emitting semiconductor chip configured to emit electromagnetic radiation with a first peak wavelength, a conversion element configured to emit electromagnetic radiation with a second peak wavelength and a dielectric layer stack arranged on the radiation-emitting semiconductor chip and the conversion element, wherein a transmittance of the dielectric layer stack for the electromagnetic radiation with the first peak wavelength and for the electromagnetic radiation with the second peak wavelength in a first angular range is greater than a threshold value, and wherein the transmittance of the dielectric layer stack for the electromagnetic radiation with the first peak wavelength and for the electromagnetic radiation with the second peak wavelength in a second angular range is less than the threshold value.

### CROSS-REFERENCE TO RELATED APPLICATIONS

This patent application is a national phase filing under section 371 of PCT/EP2022/072588, filed Aug. 11, 2022, which claims the priority of German patent application 102021123818.8, filed Sep. 15, 2021, each of which is incorporated herein by reference in its entirety.

### TECHNICAL FIELD

A radiation-emitting semiconductor component, a method for selecting a dielectric layer stack for a radiation-emitting semiconductor component, and a method for selecting a conversion material of a conversion element for a radiation-emitting semiconductor component are disclosed.

### SUMMARY

Embodiments provide a radiation-emitting semiconductor component which is particularly efficient. Further embodiments provide a method for selecting a dielectric layer stack and for selecting a conversion material of a conversion element for such a radiation-emitting semiconductor component.

A radiation-emitting semiconductor component is disclosed. For example, the radiation-emitting semiconductor component is configured to emit electromagnetic radiation from a radiation exit surface. The electromagnetic radiation emitted by the radiation-emitting semiconductor component is, for example, visible light.

According to at least one embodiment, the radiation-emitting semiconductor component comprises a radiation-emitting semiconductor chip configured to emit electromagnetic radiation with a first peak wavelength.

The radiation-emitting semiconductor chip comprises, for example, a semiconductor body. The semiconductor body has, for example, a first semiconductor layer of a first conductivity type and a second semiconductor layer of a second conductivity type different from the first conductivity type. For example, the first and second semiconductor layers are arranged stacked on top of each other, in particular grown epitaxially on top of each other. For example, the first semiconductor layer is p-doped and thus formed p-conducting. In this case, the second semiconductor layer is, for example, n-doped and thus formed n-conducting. This means that the first conductivity type is, for example, a p-conducting type and the second conductivity type is an n-conducting type.

For example, an active region is arranged between the first semiconductor layer and the second semiconductor layer. The active region is configured, for example, to generate electromagnetic radiation that is emitted from a radiation exit surface of the radiation-emitting semiconductor chip. The active region is, for example, in direct contact with the first semiconductor layer sequence and the second semiconductor layer sequence. The active region has, for example, a pn junction for generating the electromagnetic radiation, such as a single quantum well structure or a multiple quantum well structure.

The semiconductor body is based, for example, on a III-V semiconductor compound material. For example, the semiconductor body is based on gallium nitride.

For example, the electromagnetic radiation emitted by the radiation-emitting semiconductor chip is representative of a chip emission spectrum. The chip emission spectrum comprises a spectral intensity of the electromagnetic radiation emitted by the radiation-emitting semiconductor chip dependent on a wavelength λ of the electromagnetic radiation emitted by the radiation-emitting semiconductor chip. The chip emission spectrum has a maximum and a half-width. The first peak wavelength corresponds in particular to the wavelength λ at which the chip emission spectrum has the maximum.

The electromagnetic radiation emitted by the radiation-emitting semiconductor chip is, for example, near-ultraviolet radiation and/or visible light, in particular blue light. For example, the first peak wavelength is between at least 400 nm and at most 500 nm, in particular between at least 420 nm and at most 470 nm, for example approximately 435 nm. The half-width of the chip emission spectrum is, for example, between at least 10 nm and at most 50 nm, for example approximately 25 nm.

According to at least one embodiment, the radiation-emitting semiconductor component comprises a conversion element configured to emit electromagnetic radiation with a second peak wavelength. The conversion element has, for example, a main extension plane. A vertical direction is oriented perpendicular to the main extension plane and lateral directions are oriented parallel to the main extension plane.

The conversion element comprises, for example, a matrix material into which phosphor particles are introduced. The matrix material is, for example, a resin such as an epoxy, a silicone or a mixture of these materials. For example, the phosphor particles provide the wavelength-converting properties to the conversion element.

Alternatively, the conversion element is a ceramic conversion element. For example, the ceramic conversion element comprises phosphor particles that are co-sintered in a ceramic matrix material. In this case, conversion centers of the conversion element are only distributed in the phosphor particles.

Alternatively, the ceramic conversion element is a ceramic layer, in particular a conversion block. In this case, conversion centers are distributed throughout the ceramic layer.

For example, the phosphor particles comprise a first group of phosphor particles and a second group of phosphor particles. The first group of phosphor particles is configured to convert the electromagnetic radiation emitted by the radiation-emitting semiconductor chip into first secondary radiation. The second group of phosphor particles is configured to convert the electromagnetic radiation emitted by the radiation-emitting semiconductor chip into second secondary radiation, which is different from the first secondary radiation. The first secondary radiation is, for example, yellow to green light and the second secondary radiation is, for example, red light.

The conversion element converts the electromagnetic radiation emitted by the radiation-emitting semiconductor chip only partially, in particular to at most 50% or at most of 70%.

The electromagnetic radiation converted and emitted by the conversion element is representative of a conversion spectrum. The conversion spectrum comprises a spectral intensity of the electromagnetic radiation emitted by the conversion element, in particular the first secondary radiation and/or the second secondary radiation, dependent on a wavelength λ of the electromagnetic radiation emitted by the conversion element. The conversion spectrum has a maximum and a half-width. The second peak wavelength corresponds in particular to the wavelength λ at which the conversion spectrum has the maximum.

The half-width of the conversion spectrum is, for example, between at least 15 nm and at most 200 nm, for example approximately 125 nm.

According to at least one embodiment, the radiation-emitting semiconductor component comprises a dielectric layer stack arranged on the radiation-emitting semiconductor chip and the conversion element.

For example, the conversion element is arranged on the radiation-emitting semiconductor chip and the dielectric layer stack is arranged on the conversion element. The radiation-emitting semiconductor chip, the conversion element and the dielectric layer stack are arranged, for example, one above the other in vertical direction, in particular in the order indicated. For example, the radiation-emitting semiconductor chip is in direct contact with the conversion element and/or the conversion element is in direct contact with the dielectric layer stack.

The dielectric layer stack comprises, for example, several layers, each of which comprises a dielectric material. Each of the dielectric layers has, for example, a predeterminable refractive index and a predeterminable thickness. At least some of the refractive indices and at least some of the thicknesses are different for different dielectric layers.

The dielectric layer stack has a smooth outer surface, for example. A smooth outer surface here means that the outer surface has no elevations or depressions that are larger than 500 nm in the vertical direction.

According to at least one embodiment of the radiation-emitting semiconductor component, a transmittance of the dielectric layer stack is greater than a threshold value for electromagnetic radiation with the first peak wavelength and for electromagnetic radiation with the second peak wavelength in a first angular range.

The electromagnetic radiation emitted by the radiation-emitting semiconductor chip and the electromagnetic radiation emitted by the conversion element impinge on a first main surface of the dielectric layer stack facing the conversion element. The electromagnetic radiations pass through the dielectric layer stack, for example, dependent on their angle of incidence on the first main surface and/or dependent on their wavelength. The electromagnetic radiations that pass through the dielectric layer stack are emitted, for example, via a second main surface of the dielectric layer stack that is facing away from the conversion element. The transmittance is the quotient of the spectral intensity of the total electromagnetic radiation at the second main surface and the spectral intensity of the total electromagnetic radiation at the first main surface.

If the transmittance is greater than the threshold value, the electromagnetic radiation with the first peak wavelength, in particular the electromagnetic radiation emitted by the radiation-emitting semiconductor chip, and the electromagnetic radiation with the second peak wavelength, in particular the electromagnetic radiation emitted by the conversion element, can pass through the dielectric layer stack to a large extent and be coupled out via the second half-surface. “To a large extent” means here and in the following that at least 70%, in particular at least 80%, of the electromagnetic radiation is coupled out.

According to at least one embodiment of the radiation-emitting semiconductor component, the transmittance of the dielectric layer stack is smaller than the threshold value for electromagnetic radiation with the first peak wavelength and for electromagnetic radiation with the second peak wavelength in a second angular range.

If the transmittance is less than the threshold value, the electromagnetic radiation with the first peak wavelength, in particular the electromagnetic radiation emitted by the radiation-emitting semiconductor chip, and the electromagnetic radiation with the second peak wavelength, in particular the electromagnetic radiation emitted by the conversion element, are at least partially reflected back by the dielectric layer stack. “At least partially reflected back” means here and in the following that at least 20%, in particular at least 30%, of the electromagnetic radiation is reflected back.

The back-reflected electromagnetic radiation, i.e. the non-transmitted electromagnetic radiation, is in particular not absorbed by the dielectric layer stack, but is reflected back in the direction of the conversion element.

In at least one embodiment, the radiation-emitting semiconductor component comprises a radiation-emitting semiconductor chip configured to emit electromagnetic radiation with a first peak wavelength, a conversion element configured to emit electromagnetic radiation with a second peak wavelength, and a dielectric layer stack arranged on the radiation-emitting semiconductor chip and the conversion element. Further, a transmittance of the dielectric layer stack for radiation with the first peak wavelength and for radiation with the second peak wavelength in a first angular range is greater than a threshold value, and the transmittance of the dielectric layer stack for radiation with the first peak wavelength and for radiation with the second peak wavelength in a second angular range is less than the threshold value.

An idea of the radiation-emitting semiconductor component described here is, inter alia, that a directional radiation is achieved by means of the dielectric layer stack. Such a radiation-emitting semiconductor component preferably has a high efficiency for electromagnetic radiation in the first angular range.

By using the dielectric layer stack, the outer surface, in particular the second main surface, is flat. This makes such a radiation-emitting semiconductor component particularly compact, especially in the vertical direction.

According to at least one embodiment of the radiation-emitting semiconductor component, the first peak wavelength is at least 50 nm smaller than the second peak wavelength. For example, the first peak wavelength is at least 70 nm greater than the second peak wavelength.

According to at least one embodiment of the radiation-emitting semiconductor component, the emitted electromagnetic radiation of the radiation-emitting semiconductor component is white light comprising the first peak wavelength and the second peak wavelength. For example, an enveloping emission spectrum is formed by the chip emission spectrum and the conversion spectrum. The enveloping emission spectrum corresponds to a spectrum for white light.

According to at least one embodiment of the radiation-emitting semiconductor component, the threshold value is at least 0.7. For example, the threshold value is at least 0.8.

For example, the threshold value corresponds to a value of the transmittance at which the radiation of the first peak wavelength, in particular the electromagnetic radiation emitted by the radiation-emitting semiconductor chip, and the electromagnetic radiation with the second peak wavelength, in particular the electromagnetic radiation emitted by the conversion element, passes through the dielectric layer stack.

If the transmittance is 0.7, for example, the dielectric layer stack transmits 70% of the electromagnetic radiation with the first peak wavelength and the electromagnetic radiation with the second peak wavelength.

According to at least one embodiment of the radiation-emitting semiconductor component, the first angular range comprises a range of at most±60° to a surface normal of the conversion element. The surface normal extends in vertical direction. For example, the second angular range comprises a range of at most 30° to the second main surface of the dielectric layer stack.

For example, the first angular range comprises a range of at most±45° to the surface normal. In this case, the second angular range comprises a range of at most 45° to the second main surface of the dielectric layer stack.

For example, the first angular range can be predeterminable dependent on an acceptance angle of an optical element arranged above the radiation-emitting semiconductor chip.

According to at least one embodiment of the radiation-emitting semiconductor component, a surface of the radiation-emitting semiconductor chip facing the conversion element is roughened. The roughened surface is in direct contact with the conversion element, for example. The roughened surface comprises, for example, a large number of irregularly arranged elevations and depressions. Electromagnetic radiation reflected back can be advantageously scattered at these elevations and depressions.

According to at least one embodiment, the radiation-emitting semiconductor component comprises a reflective potting body. The reflective potting body comprises, for example, a matrix material into which radiation reflective particles and/or radiation scattering particles are introduced. The matrix material is, for example, a resin, such as an epoxy or a silicone, or a mixture of these materials. The radiation reflective particles provide the reflective properties to the reflective potting body.

The radiation reflective particles are, for example, TiO2 particles and/or ZrO2 particles. For example, the reflective potting body is diffusely reflective for the electromagnetic radiation of the radiation-emitting semiconductor chip and the electromagnetic radiation of the conversion element.

For example, at a layer thickness of 200 μm, the reflective potting has a reflectivity for electromagnetic radiation of at least 90%, in particular at least 95%.

According to at least one embodiment of the radiation-emitting semiconductor component, the reflective potting body covers a side surface of the radiation-emitting semiconductor chip, the conversion element and the dielectric layer stack. For example, the reflective potting body completely covers the side surface, in particular all side surfaces, of the radiation-emitting semiconductor chip, the conversion element and the dielectric layer stack. In vertical direction, the reflective potting body terminates flush with the second main surface of the dielectric layer stack, for example.

According to at least one embodiment of the radiation-emitting semiconductor component, the radiation-emitting semiconductor chip is arranged on a carrier. The carrier is, for example, a printed circuit board (PCB) or a lead frame. The radiation-emitting semiconductor chip is powered and/or controlled by the carrier, for example. Alternatively, the carrier is a ceramic substrate.

According to at least one embodiment of the radiation-emitting semiconductor component, the radiation-emitting semiconductor chip comprises a reflective element. The reflective element is arranged, for example, between the semiconductor body and the carrier. For example, the reflective element is in direct contact with the semiconductor body.

Furthermore, the radiation-emitting semiconductor chip comprises, for example, a chip carrier. The chip carrier comprises, for example, Si. The reflective element is arranged, for example, between the semiconductor body and the chip carrier. Furthermore, the chip carrier is arranged, for example, on the carrier.

The reflective element comprises, for example, a Bragg mirror and/or a metallic mirror.

With such a reflective element, electromagnetic radiation reflected back from the dielectric layer stack is advantageously reflected back to the dielectric layer stack, where it can be coupled out from the radiation-emitting semiconductor component in the first angular region.

According to at least one embodiment, the radiation-emitting semiconductor component comprises an optical element arranged above the dielectric layer stack. The optical element is spaced, for example, in vertical direction from the dielectric layer stack. The optical element is arranged, for example, in a beam path of the electromagnetic radiation emitted by the dielectric layer stack.

The optical element is, for example, a lens, in particular a convex lens or a concave lens. For example, such an optical element can be generated using a compression molding process.

According to at least one embodiment, the optical element has an acceptance angle range that is equal to or smaller than the first angle range.

Advantageously, a large proportion of the electromagnetic radiation emitted from the dielectric layer stack is received by the optical element. A large proportion here means, for example, that at least 40%, in particular 50% or 65%, of the electromagnetic radiation emitted from the dielectric layer stack is in the acceptance angle range of the optical element and can therefore be absorbed by it. If the acceptance angle range is +45°, for example, at least 50% to 65% of the electromagnetic radiation coupled out of the dielectric layer stack can be received by the optical element.

Electromagnetic radiation that does not impinge on the dielectric layer stack in the first angular range is at least partially reflected back again. This back-reflected electromagnetic radiation is scattered and reflected back in the direction of the dielectric layer stack. Due to the scattering of the electromagnetic radiation, an angle of incidence on the first main surface can be changed so that the angle of incidence is in the first angular range.

In particular, the radiation-emitting semiconductor component is used in light sources, in which directional radiation is advantageous. For example, the radiation-emitting semiconductor component is used in the automotive sector, for example in a headlight, or in projectors.

A method for selecting a dielectric layer stack for a radiation-emitting semiconductor component is further disclosed. For example, such a dielectric layer stack is suitable for the use in the radiation-emitting semiconductor component described herein. That is, all features disclosed in connection with the radiation-emitting semiconductor component are therefore also disclosed in connection with the method for selecting the dielectric layer stack, and vice versa.

According to at least one embodiment of the method, an initial dielectric layer stack is provided. For example, the initial dielectric layer stack is a virtual initial dielectric layer stack. For example, parameters are representative of the initial dielectric layer stack. The parameters can, for example, be predeterminable and stored on a computer-readable storage medium.

According to at least one embodiment, a transmittance of the initial dielectric layer stack is determined for electromagnetic radiation with a first peak wavelength and for electromagnetic radiation with a second peak wavelength for a first angular range and a second angular range, respectively. If the initial dielectric layer stack is a virtual initial dielectric layer stack, the transmittance for the first angular range and the transmittance for the second angular range is determined, for example, by means of a computer program, in particular by means of a computer.

According to at least one embodiment of the method, the dielectric layer stack is selected by adjusting the initial dielectric layer stack dependent on the transmittance in the first angular range and in the second angular range and dependent on a threshold value.

If the transmittance in the first angular range is greater than the threshold value and if the transmittance in the second angular range is less than the threshold value, the initial dielectric layer stack is selected as the dielectric layer stack. Otherwise, the initial dielectric layer stack is adjusted accordingly and the step of determining the transmittance is performed again.

According to at least one embodiment of the method, the transmittance of the dielectric layer stack is greater than the threshold value for radiation with the first peak wavelength and for radiation with the second peak wavelength in the first angular range, and the transmittance of the dielectric layer stack is less than the threshold value for radiation with the first peak wavelength and for radiation with the second peak wavelength in a second angular range.

The method for selecting the dielectric layer stack disclosed herein can be executed, at least in part, by a computer program. The computer program includes, for example, instructions that, when the computer program is executed by a computer, cause the computer to at least partially execute the method described herein.

Furthermore, a computer-readable storage medium is specified on which the computer program described here is stored.

According to at least one embodiment of the method, the initial dielectric layer stack comprises a plurality of initial dielectric layers.

According to at least one embodiment of the method, each of the initial dielectric layers has a predeterminable initial refractive index and a predeterminable initial thickness.

According to at least one embodiment of the method, at least one of the predeterminable initial refractive indices and at least one of the predeterminable initial thicknesses is increased or decreased during the adjustment of the initial dielectric layer stack. Furthermore, at least one further initial dielectric layer or several further initial dielectric layers can be added to the initial dielectric layer stack and/or one initial dielectric layer or several initial dielectric layers can be removed during the adjustment.

The initial dielectric layer stack is adjusted until a corresponding transmittance is achieved in the first angle range and in the second angle range.

Furthermore, a method for selecting a conversion material of a conversion element for a radiation-emitting semiconductor component is disclosed. For example, such a conversion element is suitable for the use in the radiation-emitting semiconductor component described herein. That is, all features disclosed in connection with the radiation-emitting semiconductor component are therefore also disclosed in connection with the method for selecting the conversion material of the conversion element, and vice versa.

According to at least one embodiment of the method, a dielectric layer stack is selected according to the method for selecting a dielectric layer stack for a radiation-emitting semiconductor component described herein above.

According to at least one embodiment of the method, an initial conversion material of an initial conversion element is provided. The initial conversion material is, for example, a virtual initial conversion material.

According to at least one embodiment of the method, an initial color location of the initial conversion element is determined dependent on the dielectric layer stack. The initial color location is determined, for example, by means of a computer program, in particular by means of a computer. Alternatively, the initial color location is determined by means of an experimental test.

According to at least one embodiment of the method, the conversion material is selected by adjusting the initial conversion material dependent on the initial color location and dependent on a predeterminable target color location.

The method disclosed herein for selecting the conversion material of the conversion element can be executed, at least in part, by a computer program. For example, the computer program comprises instructions that, when the computer program is executed by a computer, cause the computer program to at least partially execute the method described herein. Additionally or alternatively, the method for selecting the conversion material of the conversion element as disclosed herein can be performed at least in part using experimental tests.

Furthermore, a computer-readable storage medium is specified on which the computer program described here is stored.

According to at least one embodiment of the method, the initial conversion material comprises a first conversion substance.

According to at least one embodiment of the method, when adjusting the initial conversion material, the first conversion substance is replaced by another first conversion substance.

According to at least one embodiment of the method, the initial conversion material comprises a first conversion substance and a second conversion substance different from the first conversion substance.

According to at least one embodiment of the method, a mixing ratio of the first conversion substance and the second conversion substance is changed when adjusting the initial conversion material.

According to at least one embodiment of the method, the dielectric layer stack is additionally adjusted depending on the conversion material of the conversion element according to the method described herein for selecting a conversion material of a conversion element.

In addition, a method for producing a radiation-emitting semiconductor component is disclosed. For example, such a radiation-emitting semiconductor component is suitable for the use in the radiation-emitting semiconductor component described herein. That is, all features disclosed in connection with the radiation-emitting semiconductor component are therefore also disclosed in connection with the radiation-emitting semiconductor component and vice versa.

According to at least one embodiment, a conversion element is applied to a radiation-emitting semiconductor chip. The conversion element is selected according to the method for selecting a conversion material of a conversion element.

According to at least one embodiment, a dielectric layer stack is produced. The dielectric layer stack is selected according to the method for selecting a dielectric layer stack.

According to at least one embodiment, the dielectric layer stack is applied to the conversion element.

In the following, the radiation-emitting semiconductor component, the method for selecting a dielectric layer stack and the method for selecting a conversion material are explained in more detail with reference to the figures by means of exemplary embodiments.

### BRIEF DESCRIPTION OF THE DRAWINGS

FIG. 1 shows a schematic sectional view of a radiation-emitting semiconductor component according to an exemplary embodiment;

FIG. 2 shows a schematic representation of a transmission behavior of a dielectric layer stack of a radiation-emitting semiconductor component according to an exemplary embodiment;

FIG. 3 shows an exemplary representation of an enveloping emission spectrum;

FIGS. 4, 5 and 6 show transmission behaviors of a dielectric layer stack of a radiation-emitting semiconductor component according to one exemplary embodiment in each case dependent on an angle of incidence for different wavelengths;

FIGS. 7, 8 and 9 show transmission behaviors of a dielectric layer stack of a radiation-emitting semiconductor component dependent on an angle of incidence for a first peak wavelength and a second peak wavelength;

FIGS. 10, 11 and 12 show transmission behaviors of a dielectric layer stack of a radiation-emitting semiconductor component according to one exemplary embodiment in each case dependent on a wavelength for different angles of incidence;

FIGS. 13 and 14 show schematic representations of a shift of a color location dependent on a dielectric layer stack of a radiation-emitting semiconductor component according to an exemplary embodiment;

FIG. 15 shows a flowchart of a method for selecting a dielectric layer stack for a radiation-emitting semiconductor component according to an exemplary embodiment; and

FIG. 16 shows a schematic sectional view of a radiation-emitting semiconductor component according to an exemplary embodiment.

### DETAILED DESCRIPTION OF ILLUSTRATIVE EMBODIMENTS

Elements that are identical, similar or have the same effect are marked with the same reference symbols in the figures. The figures and the proportions of the elements shown in the figures are not to be regarded as being to scale. Rather, individual elements may be shown in exaggerated size for better visualization and/or better comprehensibility.

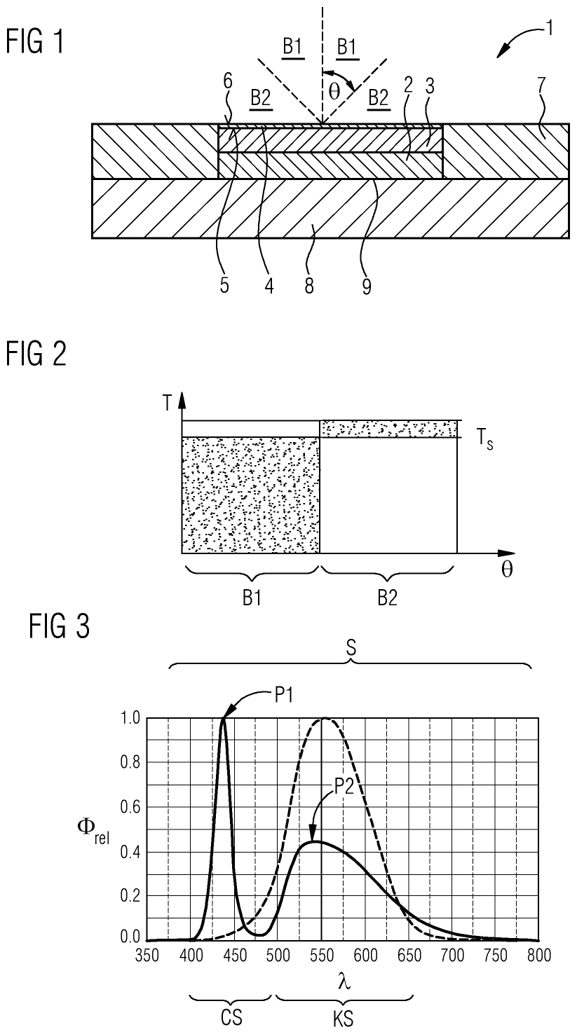

The radiation-emitting semiconductor component 1 according to the exemplary embodiment of FIG. 1 comprises a radiation-emitting semiconductor chip 2, on which a conversion element 3 is arranged. Furthermore, a dielectric layer stack 4 is arranged on the conversion element 3. The radiation-emitting semiconductor chip 2 is in direct contact with the conversion element 3 and the conversion element 3 is in direct contact with the dielectric layer stack 4.

The dielectric layer stack 4 has a first main surface 5 facing the conversion element 3 and a second main surface 6 facing away from the conversion element 3.

The radiation-emitting semiconductor chip 2 is arranged on a carrier 8. In addition, the radiation-emitting semiconductor chip 2, the conversion element 3 and the dielectric layer stack 4 are surrounded by a reflective potting body 7. The reflective potting body 7 completely covers side surfaces of the radiation-emitting semiconductor chip 2, the conversion element 3 and the dielectric layer stack 4. Furthermore, the reflective potting body 7 terminates flush with the dielectric layer stack 4, in particular the second main surface 6.

The electromagnetic radiation emitted by the radiation-emitting semiconductor chip 2 is, for example, blue light. Furthermore, a chip emission spectrum CS of the radiation-emitting semiconductor chip 2 has a maximum that corresponds to a first peak wavelength P1.

The conversion element 3 is configured to partially convert the electromagnetic radiation emitted by the radiation-emitting semiconductor chip 2 into first secondary radiation and/or second secondary radiation. The first secondary radiation is, for example, yellow to green light and/or the second secondary radiation is, for example, red light. Furthermore, a conversion spectrum KS of the conversion element 3 has a maximum that corresponds to a second peak wavelength P2.

The electromagnetic radiation emitted by the radiation-emitting semiconductor chip 2 and the electromagnetic radiation converted by the conversion element 3 each impinge on the dielectric layer stack 4 at an angle of incidence θ. The angle of incidence θ extends away from a normal of the conversion element. The electromagnetic radiation emitted by the radiation-emitting semiconductor chip 2 and the electromagnetic radiation converted by the conversion element 3 are transmitted through the dielectric layer stack 4 or reflected back towards the carrier 8 depending on the angles of incidence θ.

A transmittance for the electromagnetic radiation emitted by the radiation-emitting semiconductor chip 2 and the electromagnetic radiation converted by the conversion element 3 is defined by a quotient of the spectral intensities. Here, the quotient is a value of the spectral intensity of the total electromagnetic radiation at the second main surface 6, which is divided by a value of the spectral intensity of the total electromagnetic radiation at the first main surface 5.

The transmittance of the dielectric layer stack 4 is greater than a threshold value Tₛ for radiation with the first peak wavelength P1 and for radiation with the second peak wavelength P2 in a first angular range B1. The first angular range B1 comprises a range of at most±60° to a surface normal of the conversion element 3. This means that the electromagnetic radiation emitted by the radiation-emitting semiconductor chip 2 with the first peak wavelength P1 and the electromagnetic radiation converted by the conversion element 3 with the second peak wavelength P2, which each have an angle of incidence θ of +60° to a surface normal, are largely transmitted through the dielectric layer stack 4.

The transmittance of the dielectric layer stack 4 for radiation with the first peak wavelength P1 and for radiation with the second peak wavelength P2 is furthermore smaller than the threshold value Tₛ in a second angular range B2. Here, the second angular range B2 comprises a range from 0° to 30° to the second main surface 6 of the dielectric layer stack 4. This means that the electromagnetic radiation emitted by the radiation-emitting semiconductor chip 2 with the first peak wavelength P1 and the electromagnetic radiation converted by the conversion element 3 with the second peak wavelength P2, which each have an angle of incidence θ of 0° to 30° to the second main surface 6 of the dielectric layer stack 4, are at least partially reflected by the dielectric layer stack 4.

The back-reflected electromagnetic radiation can be reflected back towards the dielectric layer stack 4 by means of a reflective element 9. In this case, the back-reflected electromagnetic radiation can be scattered by the reflective potting and/or a roughened surface of the radiation-emitting semiconductor chip 2, so that an angle of incidence θ of the back-reflected electromagnetic radiation on the first main surface 5 changes. If such back-reflected electromagnetic radiation impinges on the first main surface 5 in the first angular range B1, a large part of it is coupled out.

For example, the first angular range B1 can be predeterminable dependent on an acceptance angle of an optical element arranged above the radiation-emitting semiconductor chip 2.

The diagram according to FIG. 2 shows on the y-axis a transmission T of the electromagnetic radiation emitted by the radiation-emitting semiconductor chip 2 with the first peak wavelength P1 and electromagnetic radiation converted by the conversion element 3 with the second peak wavelength P2 from 0% to 100%. An emission angle θ_{E} of the electromagnetic radiation emitted by the radiation-emitting semiconductor chip 2 with the first peak wavelength P1 and electromagnetic radiation converted by the conversion element 3 with the second peak wavelength P2 from 0° to 90° is plotted on the x-axis. The emission angle θ_{E} corresponds, for example, to an acceptance angle of an optical element arranged above the radiation-emitting semiconductor chip 2. Furthermore, the emission angle θ_{E} is representative of the angle of incidence θ.

For angles of incidence θ smaller than the acceptance angle, the transmission Tis greater than a threshold value Tₛ—in particular in a first angular range B1. For the remaining angles that are larger than the acceptance angle, the transmission T is smaller than the threshold value Tₛ—in particular in a second angle range B1. Areas with too low transmission B1 and too high transmission B2 are shown hatched. The threshold value Tₛ is, for example, greater than 0.7 and in particular greater than 0.8, which corresponds to a transmission T of greater than 70%, in particular greater than 80%. This transmission behavior applies to at least two wavelengths λ, the first peak wavelength P1 and the second peak wavelength P2.

The diagram in FIG. 3 shows an enveloping emission spectrum S, which is formed by a chip emission spectrum CS and a conversion spectrum KS. The enveloping emission spectrum S corresponds to a spectrum for white light. A normalized spectral intensity Φᵣₑₗ of the electromagnetic radiation emitted by the radiation-emitting semiconductor chip 2 and the electromagnetic radiation converted by the conversion element 3 is shown dependent on a wavelength λ. The chip emission spectrum CS has a maximum that corresponds to the first peak wavelength P1. Furthermore, the conversion spectrum KS has a maximum that corresponds to the second peak wavelength P2.

Both peak wavelengths P1, P2 are transmitted through the dielectric layer stack 4 in the first angular range B1 and reflected in the second angular range B2.

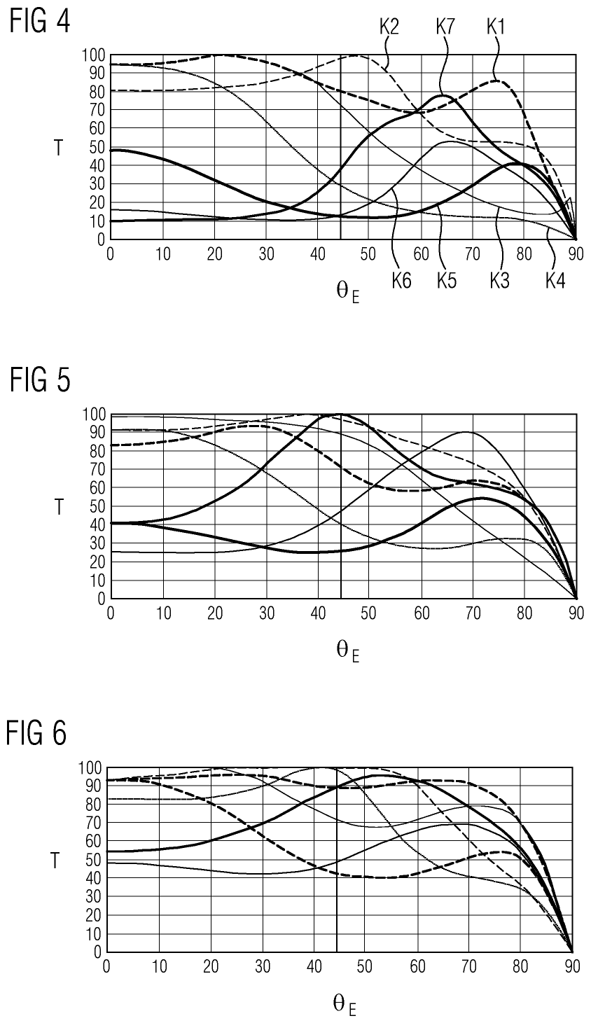

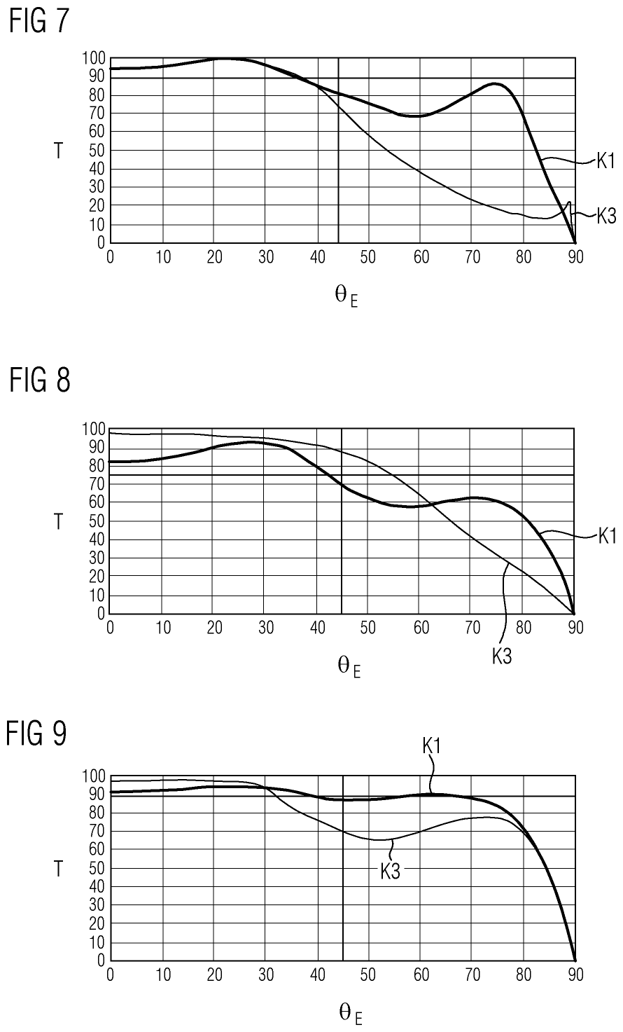

In the diagram in FIGS. 4, 5, 6, 7, 8 and 9, the transmission T in % of a dielectric layer stack 4 with respect to an emission angle θ_{E} for different wavelengths λ is shown. Curve K1 corresponds to a transmission behavior of electromagnetic radiation with a wavelength λ of 450 nm, curve K2 to a wavelength λ of 500 nm, curve K3 to a wavelength λ of 550 nm, curve K4 to a wavelength λ of 600 nm, curve K5 to a wavelength λ of 650 nm, curve K6 to a wavelength λ of 700 nm and curve K7 to a wavelength λ of 750 nm.

The curve K1 corresponds to the first peak wavelength P1 and the curve K3 corresponds to the second peak wavelength P2.

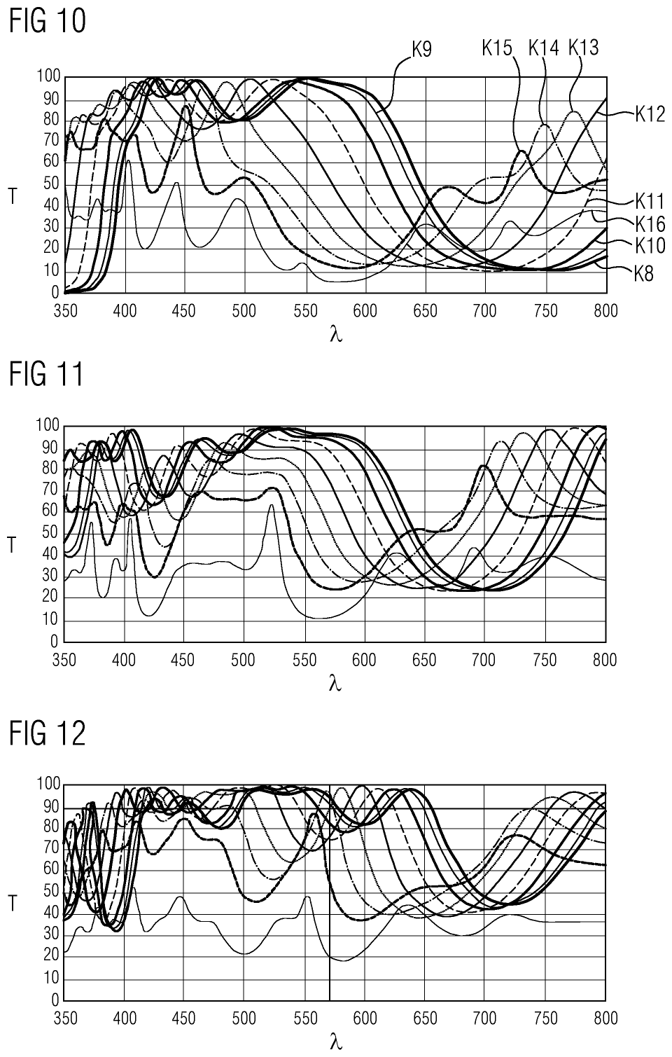

In the diagram in FIGS. 10, 11 and 12, the transmission T in % of a dielectric layer stack 4 with respect to a wavelength λ for different emission angles θ_{E} is shown. Curve K8 corresponds to a transmission behavior of electromagnetic radiation with an emission angle θ_{E} of 5°, curve K9 to an emission angle θ_{E} of 15°, curve K10 to an emission angle θ_{E} of 25°, curve K11 to an emission angle θ_{E} of 35°, curve K12 an emission angle θ_{E} of 45°, curve K13 an emission angle θ_{E} of 55°, curve K14 an emission angle θ_{E} of 65°, curve K15 an emission angle θ_{E} of 75° and curve K16 an emission angle θ_{E} of 85°.

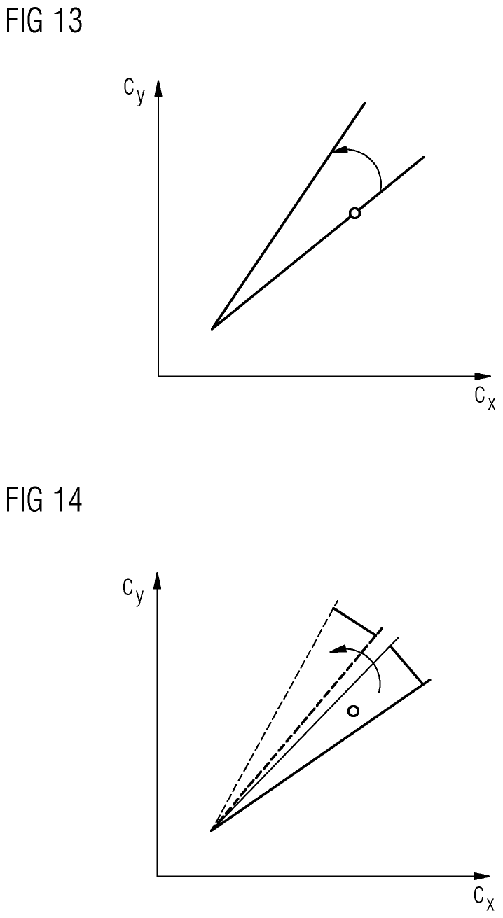

According to FIGS. 13 and 14, a predeterminable target color location is shown as a dot in a cx-cy diagram. If a concentration of conversion material in the conversion element 3 is changed, for example, the color location of the emitted electromagnetic radiation can be shifted along the straight line shown. If electromagnetic radiation passes through the dielectric layer stack 4, for example, the straight line, also known as the conversion line, is also rotated. This means that the color coordinates of electromagnetic radiation can be changed after transmission T through the dielectric layer stack 4.

FIG. 13 shows a shift of the conversion line of emitted electromagnetic radiation of a conversion element 3 with one light-emitting substance. FIG. 14 shows a shift of two conversion lines of emitted electromagnetic radiation of a conversion element 3 with two different light-emitting substances. The lower straight conversion line corresponds to a conversion line generated with a red light-emitting substance and the upper straight conversion line corresponds to a conversion line generated with a green light-emitting substance. The dashed conversion lines correspond to the shift induced by the dielectric layer stack 4.

In particular, the conversion element 3, particularly the conversion material, is selected dependent on the predeterminable target color location and the dielectric layer stack 4.

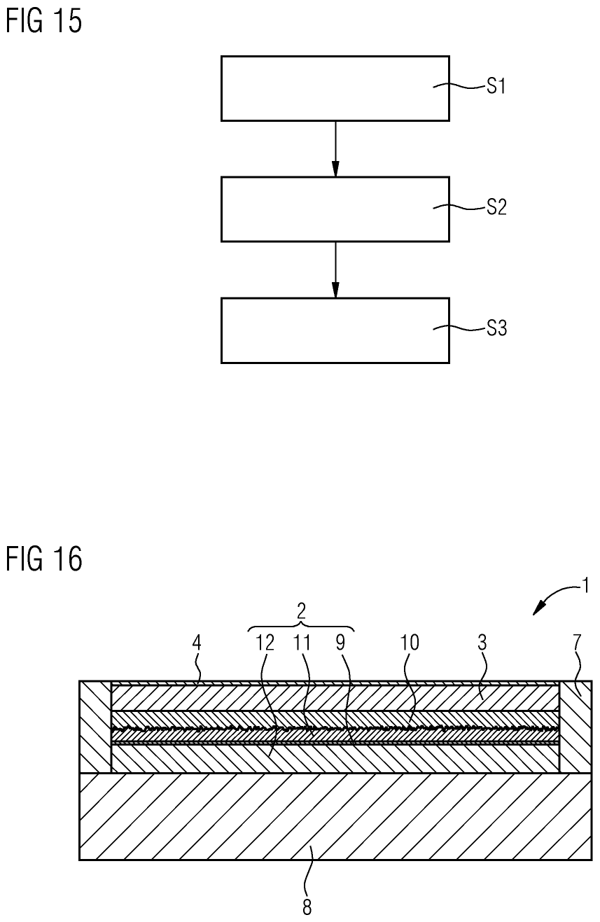

In step S1 as shown in FIG. 15, an initial dielectric layer stack is initially provided. Each of the initial dielectric layers has a predeterminable initial refractive index and a predeterminable initial thickness.

In a subsequent step S2, a transmittance of the initial dielectric layer stack is determined for electromagnetic radiation with a first peak wavelength P1 and for electromagnetic radiation with a second peak wavelength P2 for a first angular range B1 and a second angular range B2, respectively.

Subsequently, in step S3, the dielectric layer stack 4 is selected by adjusting the initial dielectric layer stack dependent on the transmittance in the first angular range B1 and in the second angular range B2 and dependent on a threshold value Tₛ.

When adjusting the initial dielectric layer stack, at least one of the predeterminable initial refractive indices and at least one of the predeterminable initial thicknesses is increased or decreased.

Steps S2 to S3 are repeated until the transmittance of the dielectric layer stack 4 for radiation with the first peak wavelength P1 and for radiation with the second peak wavelength P2 in a first angular range B1 is greater than a threshold value Tₛ and the transmittance of the dielectric layer stack 4 for radiation with the first peak wavelength P1 and for radiation with the second peak wavelength P2 in a second angular range B2 is less than the threshold value Tₛ. If this condition is met, the dielectric layer stack 4 is selected.

The radiation-emitting semiconductor chip 2 of the radiation-emitting semiconductor component 1 according to the exemplary embodiment of FIG. 16 comprises a roughened surface. A conversion element 3 is connected to a semiconductor body 11 of the radiation-emitting semiconductor chip 2 in a mechanically stable manner by means of an adhesive material, in particular an adhesive.

Furthermore, the radiation-emitting semiconductor chip 2 comprises a reflective element 9 and a chip carrier 12. The chip carrier 12 comprises, for example, Si. The reflective element 9 is arranged between the semiconductor body 11 and the chip carrier 12 and can be in direct contact thereof.

The features and exemplary embodiments described in connection with the figures can be combined with one another in accordance with further exemplary embodiments, even if not all combinations are explicitly described. Furthermore, the exemplary embodiments described in connection with the figures may alternatively or additionally have further features as described in the general part.

The invention is not limited to the description based on the exemplary embodiments. Rather, the invention includes any new feature as well as any combination of features, which includes in particular any combination of features in the claims, even if this feature or combination itself is not explicitly stated in the claims or exemplary embodiments.

1.-16. (canceled)

17. A radiation-emitting semiconductor component comprising:
a radiation-emitting semiconductor chip configured to emit electromagnetic radiation with a first peak wavelength;
a conversion element configured to emit electromagnetic radiation with a second peak wavelength; and
a dielectric layer stack arranged on the radiation-emitting semiconductor chip and the conversion element,
wherein a transmittance of the dielectric layer stack for the electromagnetic radiation with the first peak wavelength and for the electromagnetic radiation with the second peak wavelength in a first angular range is greater than a threshold value, and
wherein the transmittance of the dielectric layer stack for the electromagnetic radiation with the first peak wavelength and for the electromagnetic radiation with the second peak wavelength in a second angular range is less than the threshold value.

18. The radiation-emitting semiconductor component according to claim 17, wherein the first peak wavelength is at least 50 nm smaller than the second peak wavelength.

19. The radiation-emitting semiconductor component according to claim 17, wherein the radiation-emitting semiconductor component is configured to emit white light comprising the first peak wavelength and the second peak wavelength.

20. The radiation-emitting semiconductor component according to claim 17, wherein the threshold value is at least 0.7.

21. The radiation-emitting semiconductor component according to claim 17, wherein the first angular range comprises a range of at most±60° to a surface normal of the conversion element.

22. The radiation-emitting semiconductor component according to claim 17, wherein a surface of the radiation-emitting semiconductor chip facing the conversion element is roughened.

23. The radiation-emitting semiconductor component according to claim 17, further comprising a reflective potting body covering a side surface of the radiation-emitting semiconductor chip, the conversion element and the dielectric layer stack.

24. The radiation-emitting semiconductor component according to claim 17,
wherein the radiation-emitting semiconductor chip is arranged on a carrier, and
wherein the radiation-emitting semiconductor chip comprises a reflective element.

25. The radiation-emitting semiconductor component according to claim 17, further comprising an optical element arranged above the dielectric layer stack, wherein the optical element has an acceptance angle range that is equal to or smaller than a first angle range.

26. A method for selecting a dielectric layer stack for a radiation-emitting semiconductor component, the method comprising:
providing an initial dielectric layer stack;
determining a transmittance of the initial dielectric layer stack for electromagnetic radiation with a first peak wavelength and for electromagnetic radiation with a second peak wavelength for a first angular range and a second angular range, respectively; and
selecting the dielectric layer stack by adjusting the initial dielectric layer stack dependent on the transmittance in the first angular range and in the second angular range and dependent on a threshold value such that the transmittance of the dielectric layer stack for electromagnetic radiation with the first peak wavelength and for the electromagnetic radiation with the second peak wavelength in the first angular range is greater than the threshold value and such that the transmittance of the dielectric layer stack for radiation with the first peak wavelength and for the electromagnetic radiation with the second peak wavelength in the second angular range is less than the threshold value.

27. The method according to claim 26,
wherein the initial dielectric layer stack comprises several initial dielectric layers,
wherein each of the initial dielectric layers has a predeterminable initial refractive index and a predeterminable initial thickness, and
wherein, while adjusting the initial dielectric layer stack, at least one of the predeterminable initial refractive indices and at least one of the predeterminable initial thicknesses is increased or reduced.

28. A method for selecting a conversion material of a conversion element for the radiation-emitting semiconductor component, the method comprising:
selecting the dielectric layer stack by performing the method according to claim 26;
providing an initial conversion material of an initial conversion element;
determining an initial color location of the initial conversion element dependent on the dielectric layer stack; and
selecting the conversion material by adjusting the initial conversion material depending on the initial color location and depending on a predeterminable target color location.

29. The method according to claim 28,
wherein the initial conversion material comprises a first conversion substance, and
wherein, when adjusting the initial conversion material, the first conversion substance is replaced by another first conversion substance.

30. The method according to claim 28,
wherein the initial conversion material comprises a first conversion substance and a second conversion substance different from the first conversion substance, and
wherein a mixing ratio of the first conversion substance and the second conversion substance is changed when adjusting the initial conversion material.

31. The method according to claim 28, wherein the dielectric layer stack is additionally adjusted depending on the conversion material of the conversion element.

32. A method for producing the radiation-emitting semiconductor component, the method comprising:
applying a conversion element to a radiation-emitting semiconductor chip;
producing the dielectric layer stack selected according to the method according to claim 26; and
applying the dielectric layer stack to the conversion element.
